(19) United States
(12) Patent Application Publication
(10) Pub. No.: US 2023/0155075 A1
(43) Pub. Date: May 18, 2023

(54) LIGHT EMITTING DEVICES INCLUDING A QUANTUM DOT COLOR CONVERSION MATERIAL AND METHOD OF MAKING THEREOF

(71) Applicant: NANOSYS, INC., Milpitas, CA (US)

(72) Inventors: Jason HARTLOVE, Los Altos, CA (US); Saket CHADDA, San Jose, CA (US); Ernest C. LEE, Palo Alto, CA (US); Brian KIM, Santa Clara, CA (US); Homer ANTONIADIS, Mountain View, CA (US); Ravisubhash TANGIRALA, Fremont, CA (US); David OLMEIJER, San Francisco, CA (US)

(21) Appl. No.: 18/055,572

(22) Filed: Nov. 15, 2022

Related U.S. Application Data
(60) Provisional application No. 63/279,964, filed on Nov. 16, 2021.

(51) Int. Cl. H01L 33/50; H01L 25/075; H01L 33/60

(52) U.S. Cl. CPC H01L 33/502; H01L 25/0753; H01L 33/507; H01L 33/60; H01L 33/32

(57) ABSTRACT

A light emitting device includes a first optical cavity bounded by cavity walls, a first light emitting diode located in the first optical cavity and configured to emit blue or ultraviolet radiation first incident photons, a first color conversion material located over the first light emitting diode and configured to absorb the first incident photons emitted by the light emitting diode and to generate first converted photons having a longer peak wavelength than a peak wavelength of the first incident photons, and a first color selector located over the first color conversion material and configured to absorb or reflect the first incident photons and to transmit the first converted photons.

### FIELD

This disclosure relates to light emitting devices, and particularly to light emitting diodes formed in optical cavities with a color conversion material and methods of fabricating the same.

### BACKGROUND

Light emitting devices are used in electronic displays, such as backlights in liquid crystal displays in laptops and televisions. Light emitting devices include light emitting diodes (LEDs) and various other types of electronic devices configured to emit light.

For light emitting devices, such as LEDs, the emission wavelength is determined by the band gap of the active region of the LED together with size dependent quantum confinement effects. Often the active region includes one or more bulk semiconductor layers or quantum wells (QW). For III-nitride based LED devices, such as GaN based devices, the active region (e.g., bulk semiconductor layer or QW well layer) material may be ternary, having a composition such as InₓGa₁₋ₓN, where 0<x<1.

The band gap of such III-nitride materials is dependent on the amount of In incorporated in the active region. Higher indium incorporation yields a smaller band gap and thus longer wavelength of the emitted light. As used herein, the term “wavelength” refers to the peak emission wavelength of the LED. It should be understood that a typical emission spectra of a semiconductor LED is a narrow band of wavelength centered around the peak wavelength.

### SUMMARY

An embodiment light emitting device includes a first optical cavity bounded by at least one first cavity wall, a first light emitting diode located in the first optical cavity and configured to emit blue or ultraviolet radiation first incident photons, a first color conversion material located over the first light emitting diode and configured to absorb the first incident photons emitted by the light emitting diode and to generate first converted photons having a longer peak wavelength than a peak wavelength of the first incident photons, and a first color selector located over the first color conversion material and configured to absorb or reflect the first incident photons and to transmit the first converted photons.

An embodiment method of forming an array of light emitting devices comprises forming a first via in a matrix material, depositing a first plurality of quantum dots in the first via to form a first portion of the color conversion material layer corresponding to a first color, forming a second via in the matrix material, depositing a second plurality of quantum dots in the second via to form a second portion of the color conversion material layer corresponding to a second color, forming a third via in the matrix material, and depositing a third plurality of quantum dots in the third via to form a third portion of the color conversion material layer corresponding to a third color. The first plurality of quantum dots are located over a first light emitting diode, the second plurality of quantum dots are located over a second light emitting diode, and the third plurality of quantum dots are located over a third light emitting diode.

### BRIEF DESCRIPTION OF THE DRAWINGS

FIG. 1A is a vertical cross-sectional view of an intermediate structure that may be used in the formation of an array of light emitting devices, according to various embodiments.

FIG. 1B is a vertical cross-sectional view of a further intermediate structure that may be used in the formation of an array of light emitting devices, according to various embodiments.

FIG. 1C is a vertical cross-sectional view of a further intermediate structure that may be used in the formation of an array of light emitting devices, according to various embodiments.

FIG. 1D is a vertical cross-sectional view of an array of light emitting devices, according to various embodiments.

FIG. 1E is a vertical cross-sectional view of a further array of light emitting devices, according to various embodiments.

FIG. 2A is a top perspective view of a first patterned matrix having a plurality of vias formed therein, according to various embodiments.

FIG. 2B is a top perspective view of a second patterned matrix having a plurality of vias formed therein, according to various embodiments.

FIG. 3A is a vertical cross-sectional view of an intermediate structure that may be used in the formation of an array of light emitting devices, according to various embodiments.

FIG. 3B is a vertical cross-sectional view of a further intermediate structure that may be used in the formation of an array of light emitting devices, according to various embodiments.

FIG. 3C is a vertical cross-sectional view of a further intermediate structure that may be used in the formation of an array of light emitting devices, according to various embodiments.

FIG. 3D is a vertical cross-sectional view of a further intermediate structure that may be used in the formation of an array of light emitting devices, according to various embodiments.

FIG. 3E is a vertical cross-sectional view of a further intermediate structure that may be used in the formation of an array of light emitting devices, according to various embodiments.

FIG. 3F is a vertical cross-sectional view of a further intermediate structure that may be used in the formation of an array of light emitting devices, according to various embodiments.

FIG. 3G is a vertical cross-sectional view of a further intermediate structure that may be used in the formation of an array of light emitting devices, according to various embodiments.

FIG. 3H is a vertical cross-sectional view of a further intermediate structure that may be used in the formation of an array of light emitting devices, according to various embodiments.

FIG. 3I is a vertical cross-sectional view of a further intermediate structure that may be used in the formation of an array of light emitting devices, according to various embodiments.

FIG. 3J is a vertical cross-sectional view of a further intermediate structure that may be used in the formation of an array of light emitting devices, according to various embodiments.

FIG. 3K is a vertical cross-sectional view of a further intermediate structure that may be used in the formation of an array of light emitting devices, according to various embodiments.

FIG. 3L is a vertical cross-sectional view of a further intermediate structure that may be used in the formation of an array of light emitting devices, according to various embodiments.

FIG. 4A is a vertical cross-sectional view of an intermediate structure that may be used in the formation of an array of light emitting devices, according to various embodiments.

FIG. 4B is a vertical cross-sectional view of a further intermediate structure that may be used in the formation of an array of light emitting devices, according to various embodiments.

FIG. 4C is a vertical cross-sectional view of a further intermediate structure that may be used in the formation of an array of light emitting devices, according to various embodiments.

FIG. 4D is a vertical cross-sectional view of a further intermediate structure that may be used in the formation of an array of light emitting devices, according to various embodiments.

FIG. 4E is a vertical cross-sectional view of a further intermediate structure that may be used in the formation of an array of light emitting devices, according to various embodiments.

FIG. 4F is a vertical cross-sectional view of a further intermediate structure that may be used in the formation of an array of light emitting devices, according to various embodiments.

FIG. 4G is a vertical cross-sectional view of a further intermediate structure that may be used in the formation of an array of light emitting devices, according to various embodiments.

FIG. 4H is a vertical cross-sectional view of a further intermediate structure that may be used in the formation of an array of light emitting devices, according to various embodiments.

FIG. 4I is a vertical cross-sectional view of a further intermediate structure that may be used in the formation of an array of light emitting devices, according to various embodiments.

FIG. 4J is a vertical cross-sectional view of a further intermediate structure that may be used in the formation of an array of light emitting devices, according to various embodiments.

FIG. 4K is a vertical cross-sectional view of a further intermediate structure that may be used in the formation of an array of light emitting devices, according to various embodiments.

FIG. 4L is a vertical cross-sectional view of a further intermediate structure that may be used in the formation of an array of light emitting devices, according to various embodiments.

FIG. 4M is a vertical cross-sectional view of a further intermediate structure that may be used in the formation of an array of light emitting devices, according to various embodiments.

FIG. 4N is a vertical cross-sectional view of a further intermediate structure that may be used in the formation of an array of light emitting devices, according to various embodiments.

FIG. 4O is a vertical cross-sectional view of a further intermediate structure that may be used in the formation of an array of light emitting devices, according to various embodiments.

FIG. 4P is a vertical cross-sectional view of a further intermediate structure that may be used in the formation of an array of light emitting devices, according to various embodiments.

FIG. 5A is a vertical cross-sectional view of an intermediate structure that may be used in the formation of an array of light emitting devices, according to various embodiments.

FIG. 5B is a vertical cross-sectional view of a further intermediate structure that may be used in the formation of an array of light emitting devices, according to various embodiments.

FIG. 5C is a vertical cross-sectional view of a further intermediate structure that may be used in the formation of an array of light emitting devices, according to various embodiments.

FIG. 5D is a vertical cross-sectional view of a further intermediate structure that may be used in the formation of an array of light emitting devices, according to various embodiments.

FIG. 5E is a vertical cross-sectional view of a further intermediate structure that may be used in the formation of an array of light emitting devices, according to various embodiments.

FIG. 5F is a vertical cross-sectional view of a further intermediate structure that may be used in the formation of an array of light emitting devices, according to various embodiments.

FIG. 5G is a vertical cross-sectional view of a further intermediate structure that may be used in the formation of an array of light emitting devices, according to various embodiments.

### DETAILED DESCRIPTION

A display device, such as a direct view display may be formed from an ordered array of pixels. Each pixel may include a set of subpixels that emit light at a respective peak wavelength. For example, a pixel may include a red subpixel, a green subpixel, and a blue subpixel. Each subpixel may include one or more light emitting diodes that emit light of a particular wavelength. A traditional arrangement is to have red, green, and blue (RGB) subpixels within each pixel. Each pixel may be driven by a backplane circuit such that any combination of colors within a color gamut may be shown on the display for each pixel. The display panel may be formed by a process in which LED subpixels are soldered to, or otherwise electrically attached to, a bond pad located on a backplane. The bond pad may be electrically driven by the backplane circuit and other driving electronics.

Various embodiments provide a light emitting device configured to create high efficiency red, green, blue, and/or other color pixelated light from a shorter wavelength excitation source using photonically pumped quantum dots in a vertical cavity structure. Embodiment micron-scale light emitting diodes (micro-LED) which have a length and width less than 100 microns, such as 5 to 20 microns, may be used in display devices. This emerging technology offers ultimate black levels by using individual LEDs at each pixel location of a display device. Further, each pixel may be configured to generate a single color of light. A backplane upon which individual LEDs may be attached may include a substrate (e.g., plastic, glass, semiconductor, etc.) with thin-film transistor (TFT) structures, silicon CMOS, or other driver circuitry that may be configured to apply a voltage or current to each LED independently. For example, the backplane may include TFTs on a glass or plastic substrate, or bulk silicon transistors (e.g., transistors in a CMOS configuration) on a bulk silicon substrate or on a silicon-on-insulator (SOI) substrate. While micro-LEDs are described in the embodiments below, it should be noted that other types of LEDs (e.g., nanowire or other nanostructure LEDs) or macro-LEDs having a size (e.g., width and length) greater than 100 microns may also be used instead of or in addition to the micro-LEDs.

In some embodiments, a size of each micro-LED may be smaller than a pitch of the pixels used in a particular display device, such as a direct view display device or another display device. For example, a 300 ppi display may have pixels having a pitch of approximately 85 microns, while a typical micro-LED for such a display may have a width that is approximately 20 microns. Micro-LEDs that include an indium-doped GaN material (i.e., LEDs that emit a color that depends on indium doping of GaN) may suffer degradation of efficiency and uniformity with decreasing LED size (e.g., sizes less than 10 microns) due to difficulties associated with indium doping of GaN crystal structures. Thus, longer peak wavelength emitting III-nitride micro-LEDs (e.g., red LEDs) which utilize a higher indium content in their active regions may have insufficient efficiency and uniformity due to the degraded indium doping.

Some embodiments of the present disclosure include a photonic emitter based on a LED having an undoped GaN active region (e.g., a micro-LED having a GaN light emitting active layer) or a low indium doped InGaN active region (e.g., a micro-LED having a low indium content InGaN light emitting active layer) coupled with a photonically pumped color conversion material. Such LEDs may be ultraviolet (UV) radiation or blue light emitting micro-LEDs having a peak emission wavelength in the UV radiation or blue light spectral region (e.g., 370 to 460 nm, such as 390 to 420 nm, for example 400 to 410 nm). As used herein, the blue light spectral region includes blue and violet colors as perceived by the human observer.

In one embodiment, the color conversion material may include quantum dots. The quantum dots may be configured to absorb photons generated by the GaN emitter and to generate various colors of light depending on the properties of the quantum dots (e.g., quantum dot size and material composition). Such structures avoid problems associated with indium doping of small GaN structures.

In the size regime (i.e., sizes less than 10 microns) appropriate for augmented reality (AR) displays (e.g., smart glasses) and other applications, the use of a undoped GaN or low indium doped GaN LED active region and photonically pumped quantum dots to create various colors may provide display devices having better uniformity across an array of micro-LEDs. Such arrays may also exhibit higher efficiency than systems having colored LEDs based on relatively high indium doped GaN (e.g., red LEDs containing a higher amount of indium than blue LEDs). The increased efficiency and uniformity may be achieved because quantum dots may be manufactured with a high degree of uniformity of size and material composition. Such uniform quantum dots have corresponding uniform (i.e., narrow linewidth) emission properties.

Extraction of light emitted by micro-LEDs may be increasingly challenging with decreasing pixel pitch and micro-LED size. Disclosed embodiments provide improved optical extraction of photons (e.g., along a specific direction) generated by the quantum dots, while maintaining high efficiency by avoiding loss of photons to absorbing surfaces. Disclosed systems may also prevent or reduce pump photons from escaping the device, thereby ensuring purity of the color emitted by a given micro-LED. This may be accomplished by forming optical cavity walls that are reflective, including a light extracting material layer, and including other light extracting structures, such as micro lenses and/or a distributed Bragg reflector (DBR).

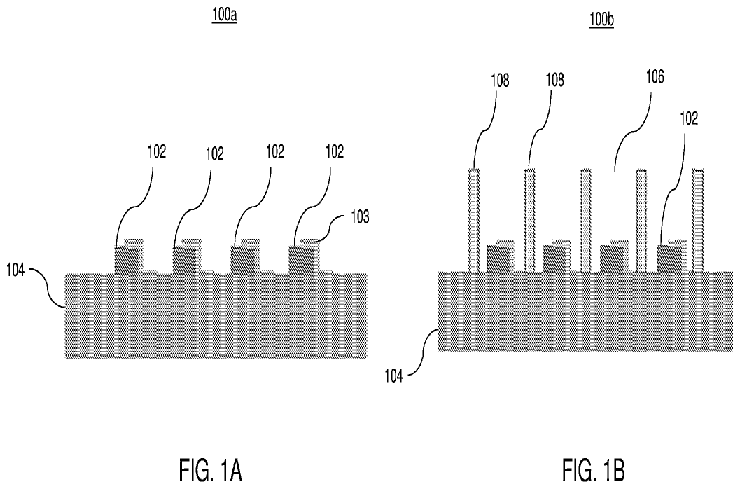

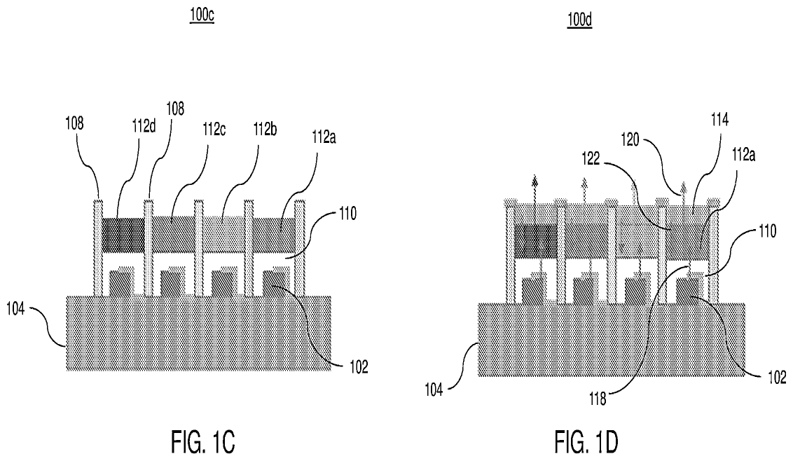

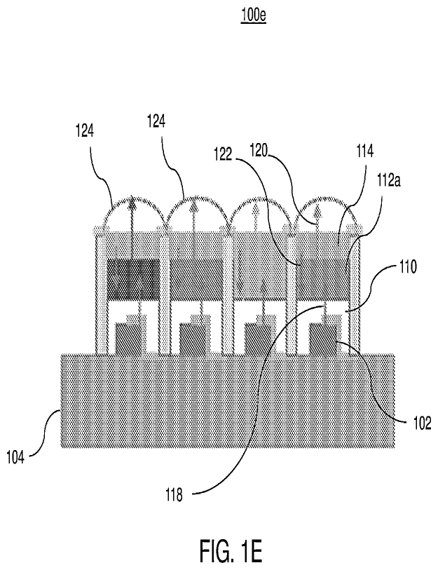

FIG. 1A is a vertical cross-sectional view of an intermediate structure 100a that may be used in the formation of an array of light emitting devices, according to various embodiments. The intermediate structure 100a may include a plurality of micro-LEDs 102 formed on a substrate 104. As described above, the micro-LEDs 102 may include a micro-LEDs which have peak emission wavelength in the UV radiation or blue light spectral region (e.g., UV or blue emitting micro-LEDs, also referred to as UV or blue LEDs). Such LEDs may include undoped GaN active regions that are configured to emit ultraviolet (UV) photons and/or blue spectral range photons.

In one embodiment, the micro-LEDs 102 may have at least one electrode 103 located on the top of the LED and facing away from the substrate 104. The electrode 103 may comprise an anode or a cathode electrode. In one embodiment, the micro-LEDs 102 may comprise vertical LEDs in which the second electrode (not shown for clarity) is located between the substrate 104 and the bottom of the micro-LED 102. In another embodiment, the micro-LEDs may comprise lateral LEDs in which both electrodes are located on the same side of the LED (e.g., on top or on bottom sides of the LED).

The substrate 104 may be a backplane having electrical circuitry (e.g., TFT and/or CMOS circuits) configured to supply voltages and currents to the micro-LEDs 102 via the electrodes (including the electrodes 103) to thereby control light emission by the micro-LEDs 102. A backplane may be an active or passive matrix backplane substrate for driving LEDs. As used herein, a “backplane substrate” refers to any substrate configured to affix multiple devices thereupon. In one embodiment, the backplane may include a substrate including silicon, glass, plastic, and/or at least other material that may provide structural support to devices attached thereto. In one embodiment, the backplane substrate may be a passive backplane substrate, in which metal interconnect structures (not shown) including metallization lines are present, for example, in a crisscross grid and dedicated active devices (e.g., TFTs) for each LED are not present. In another embodiment, the backplane substrate may be an active backplane substrate, which includes metal interconnect structures as a crisscross grid of conductive lines and further includes dedicated active devices (e.g., CMOS transistors or TFTs) for each LED at one or more intersections of the crisscross grid of conductive lines.

FIG. 1B is a vertical cross-sectional view of a further intermediate structure 100b that may be used in the formation of an array of light emitting devices, according to various embodiments. Intermediate structure 100b includes a plurality of optical cavities 106 formed over the micro-LEDs 102. Each optical cavity may be bounded by cavity walls 108. The optical cavities 106 may be constructed using a reflective material which has suitable mechanical properties to form high aspect ratio cavities (e.g., 5 microns or less, such as 1-2 microns, in diameter, and 10 microns or more, such as 20-30 microns, in height) with relatively thin side walls 108. The cavity walls 108 may have a thickness of less than 10 microns, such as 0.5-5 microns, including 1-2 microns. The cavity walls 108 form an insulating matrix.

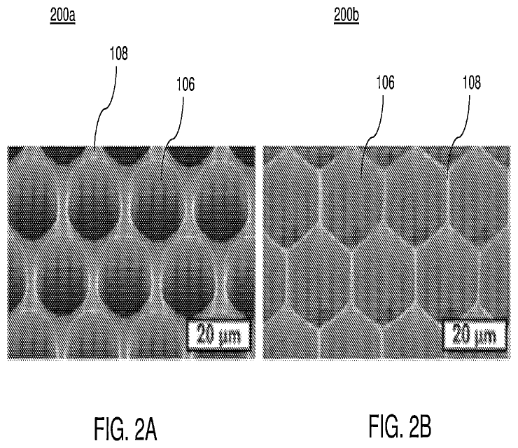

The matrix material may be chosen to be compatible with both thermal evaporative processing steps and solvent based fluidic depositions and evaporation. One such matrix material is alumina, although silica, titania, or other insulating metal oxide materials may be used. Various materials that are typically used to fabricate micro-electromechanical (MEMS) devices may be used to form the optical cavities 106 bounded by cavity walls 108 made of an electrically insulating material (e.g., alumina). Such materials have a relatively high index of refraction and are suitable for forming structures having high aspect ratios. A layer of such matrix material (not shown in FIG. 1B) may be grown or deposited on the micro-LED 102 array located on the substrate 104 and techniques such as etching and other micro machining approaches may be used to generate optical cavities 106 in the material. FIG. 2A is a top perspective view of a matrix 200a having a plurality of cylindrical optical cavities 106 bounded by cavity walls 108. FIG. 2B is a top perspective view of a matrix 200b having a plurality of hexagonal optical cavities 106 bounded by cavity walls 108.

In one embodiment, a voltage may be applied to an anode or cathode electrode 103 of the micro-LEDs 102 to thereby form one side of an etch bias. For example, if the matrix 200a or 200b (i.e., the cavity walls 108) comprise alumina, then the porous alumina may be formed by anodic oxidation. In this embodiment, an aluminum metal layer may be deposited over the micro-LEDs 102, and then electrochemically anodized to form a porous anodic alumina matrix with optical cavities (i.e., pores) 106 bounded by anodic alumina walls 108. The substrate 104 containing the aluminum layer is placed in an acid electrolyte (e.g., oxalic acid, chromic acid, sulfuric acid and/or phosphoric acid), and a voltage is applied to the electrodes 103 of the micro-LEDs 102 and/or to an external electrode to form the porous anodic alumina matrix containing the optical cavities (i.e., pores) 106 bounded by the alumina cavity walls 108. The optical cavities 106 may be arranged in a hexagonal array in an anodic alumina matrix.

FIG. 1C is a vertical cross-sectional view of a further intermediate structure 100c that may be used in the formation of an array of light emitting devices, according to various embodiments. Intermediate structure 100c may include a light extracting material layer 110 and a color conversion material (112a, 112b, 112c, 112d) formed in the optical cavities 106 over the array of micro-LEDs 102. The light extracting material layer 110 may have an index of refraction that is lower than an index of refraction of the material forming the cavity walls 108. For example, the light extracting material layer 110 may have an index of refraction of less than 1.7, such as 1.3 to 1.5 for alumina cavity walls 108. The lower refractive index of the light extracting material layer 110 may cause pump photons (i.e., photons generated by the micro-LEDs 102) to be reflected from cavity walls 108 rather than being absorbed by or transmitted through that cavity walls 108. Such reflection prevents loss of photons and thereby acts to increase the quantum efficiency of the device.

Various polymer materials may be used as a light extracting material layer 110. One such polymer is Jet-144 (i.e., an inkjet compatible polymer), which has an index of refraction of 1.44 and which may be deposited into the optical cavities 106 using an inkjet system. A thickness of the cavity walls 108 may be configured to be as thick as possible to increase a probability that photons that do not reflect from the cavity walls 108 are absorbed (i.e., extinguished) so that they do no penetrate into an adjacent cavity.

The light extracting material layer 110 may be deposited using various techniques including ink jet, vacuum, pressure, and/or gravitational deposition. After deposition, the polymer may be cross-linked, for example, by exposure to ultra-violet (UV) radiation. In other embodiments, a solvent in which the polymer is dissolved may be drawn out by evaporation leaving a residual cross-linked polymer as the light extracting material layer 110 in each cavity. In various embodiments, the light extracting material layer 110 may be formed with various thicknesses and may or may not contain additional light scattering materials, such as TiO₂ or SiO₂ nano or micro beads. The light extracting material layer 110 partially fills the optical cavities 106 such that empty cavity space remains over the top of the light extracting material layer 110 in each cavity.

The color conversion material (112a, 112b, 112c, 112d) may then be formed in the optical cavities 106 (e.g., see FIG. 1B) over the light extracting material layer 110 (e.g., see FIG. 1C). The color conversion material (112a, 112b, 112c, 112d) may include quantum dots corresponding to various different colors. In this example, the color conversion material (112a, 112b, 112c, 112d) the plurality of first quantum dots 112a, a plurality of second quantum dots 112b, and plurality of third quantum dots 112c, and a plurality of fourth quantum dots 112d, which are configured to convert UV pump photons into photons having first, second, third, and fourth colors, respectively. The second and third colors may comprise different peak wavelengths in the green color spectrum range. Alternatively, only three quantum dot colors may be used. The quantum dots may comprise 1 to 10 nm, such as 2 to 8 nm nanocrystals of a compound semiconductor material, such as a Group III-V semiconductor material (e.g., indium phosphide, as described in U.S. Pat. No. 9,884,763 B 1, incorporated herein by reference in its entirety), a Group II-VI semiconductor material (e.g., ZnSe, ZnS, ZnTe, CdS, CdSe, etc., core-shell quantum dots, as described in U.S Patent Application Publication US 2017/0250322 A1, incorporated herein by reference in its entirety), and/or Group I-III-VI semiconductor material (e.g., AgInGaS/AgGaS core-shell quantum dots, as described in U.S. Pat. No. 10,927,294 B2, incorporated herein by reference in its entirety). The quantum dots may emit different color light (e.g., red, green or blue) depending on their diameter. The larger dots emit longer wavelength light while the smaller dots emit shorter wavelength light. The quantum dots may be suspended in a material (e.g., a polymer such as polyimide) having a different (e.g., higher) index of refraction from that of the light extracting material 110. For example, the polyimide material may be a refractive index of 1.6 to 1.75, such as about 1.7.

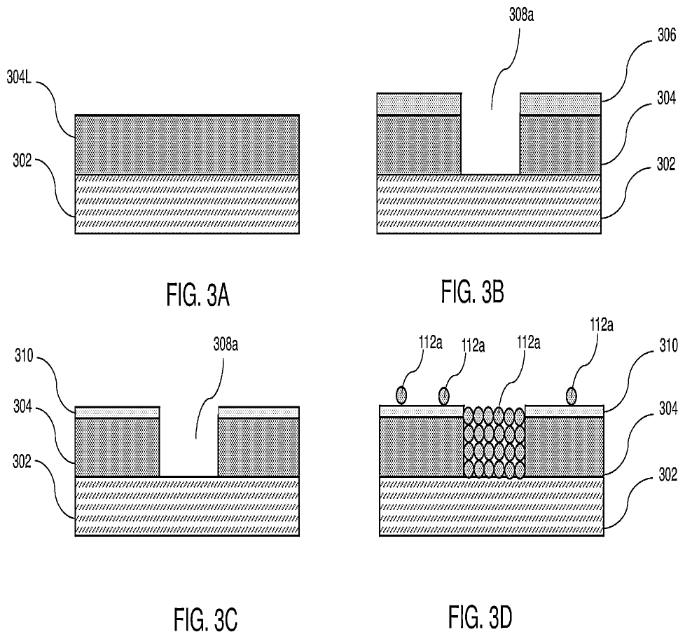

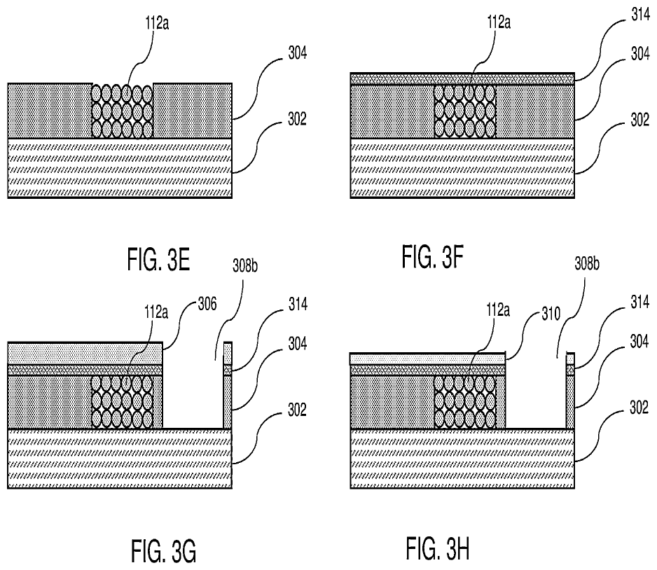

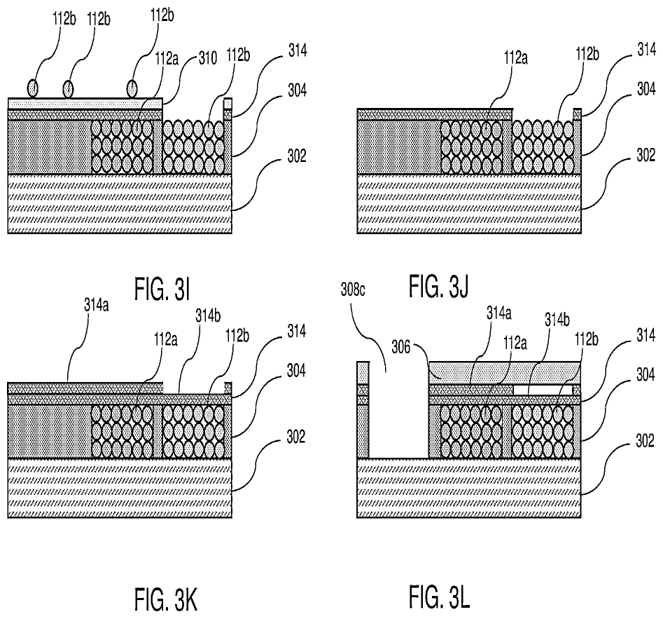

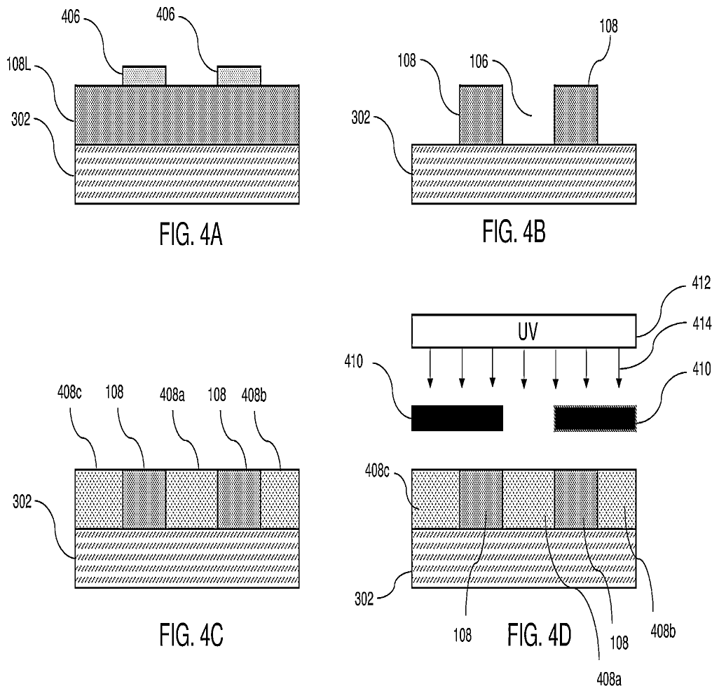

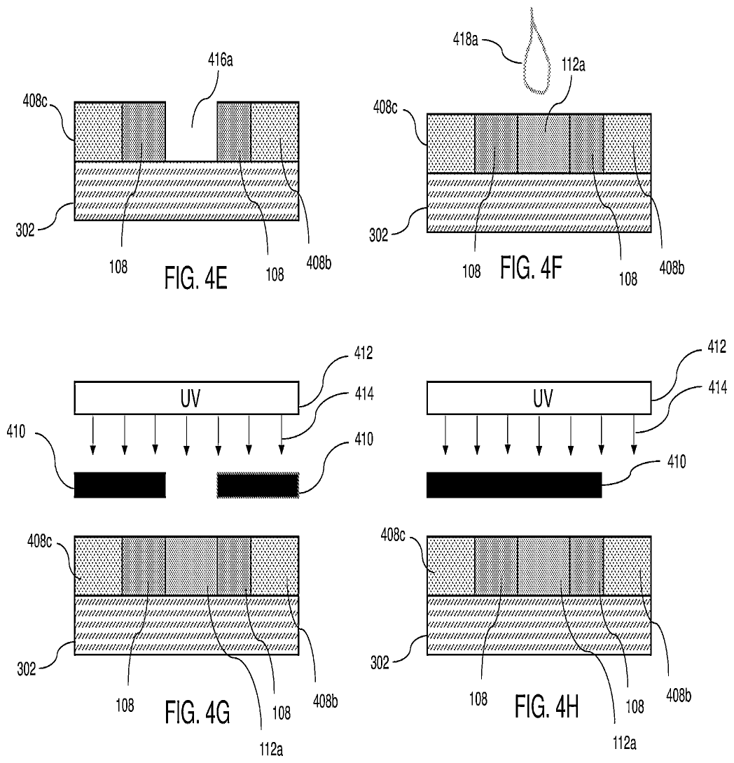

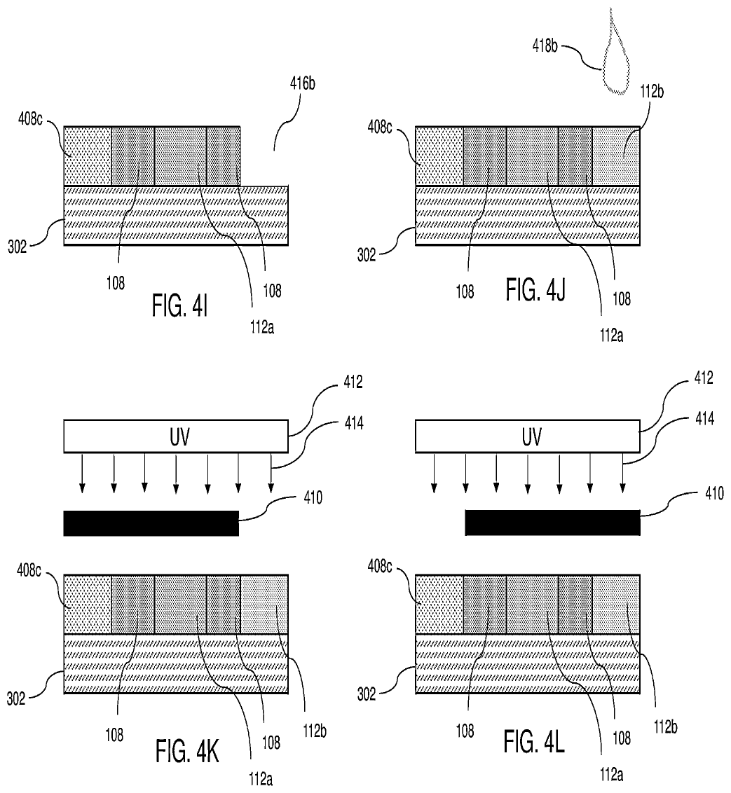

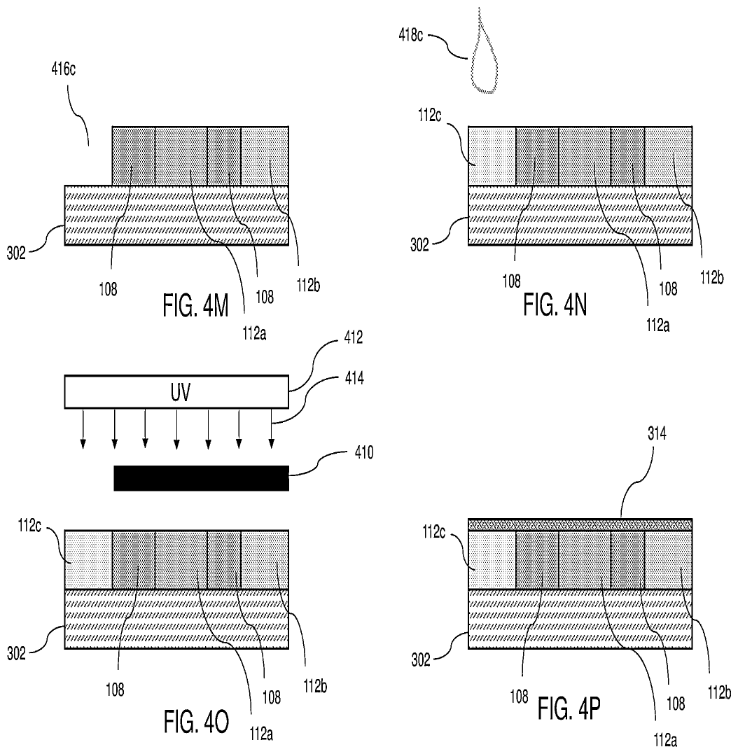

As described in greater detail below (e.g., with reference to FIGS. 3A to 4P), quantum dots corresponding to various colors may be selectively deposited in respective cavities. For example, as described with reference to FIGS. 3A to 3L, below, first cavities may be formed by etching first vias in a matrix material. First quantum dots corresponding to first color may then be introduced into the first cavities and a layer of protective material may then be formed over the first quantum dots. The process may then be repeated to form second cavities, third cavities, etc., and to respectively introduce second quantum dots, third quantum dots, etc. into the respective cavities.

In other embodiments (e.g., see FIGS. 4A to 4P), a photoresist may be deposited over all cavities except a plurality of first cavities. A first layer of quantum dots configured to generate a first color (e.g., red) may then be deposed into the plurality of first cavities corresponding to subpixels having the first color. A polymer in which the first quantum dots are suspended may then be cross linked by evaporation or by exposure to UV light. The process may then be repeated for the other optical cavities to respectively deposit quantum dots configured to generate other color light (e.g., green and blue).

An optional organic planarization layer may be formed over the color conversion material. The color conversion material and the optional organic planarization layer may partially fill the optical cavities 106.

FIG. 1D is a vertical cross-sectional view of an array 100d of light emitting devices, according to various embodiments. As shown, the array 100d may include color selector 114 formed in and/or over the optical cavities 106. The color selector 114 may comprise a color filter array and/or a distributed Bragg reflector. In one embodiment, the color selector 114 may be formed in the optical cavities and may extend to the top of the cavity walls 108 such that the optical cavities 106 are completely filled with the above materials.

The color conversion material (112a, 112b, 112c, 112d) may be configured to absorb the pump photons 118 and to convert them to emitted converted photons (e.g., visible light, such as red, green or blue light) 120. In some embodiments, the color conversion material (112a, 112b, 112c, 112d) may not be sufficiently thick and/or dense to fully convert all pump photons 118 into converted photons 120. Thus, the color selector 114 formed over the color conversion material (112a, 112b, 112c, 112d) absorbs and/or reflects all or a portion of the pump photons 118 that are not converted by the color conversion material (112a, 112b, 112c, 112d), without absorbing and/or reflecting the converted photon 120 emitted by the color conversion material.

Each of the micro-LEDs 102 may be configured to emit pump photons 118 having a common wavelength or within a range of the target wavelengths. For example, GaN-based micro-LEDs 102 may emit pump photons 118 having a wavelength that is 400 to 410 nm, such as approximately 405 nm (i.e., in the blue or near-UV part of the electromagnetic spectrum). The micro-LEDs 102 may exhibit a high degree of uniformity and may exhibit high efficiency. However, slight variations in the wavelength of such micro-LEDs 102 may not be easily visible to the eye. Further, any leakage of pump photons 118 through the color conversion material (112a, 112b, 112c, 112d) may cause minimal degradation of the color purity of converted photons 120.

In one embodiment, the color selector 114 includes a color filter array comprising an organic dye embedded in an organic polymer. The dye may be configured to absorb UV radiation of the pump photons 118 but to not absorb blue, green, or red light of the converted photons. Optionally, a different dye may be applied over each of the colored subpixels (e.g., red, green, and blue subpixels). For example, a first dye filter material configured to primarily transmit red light may be applied to red subpixels, a second dye filter material configured to primarily transmit green light may be applied to green subpixels, and third dye filter material configured to primarily transmit blue light may be applied to blue subpixels. The color filters may by formed using a further photolithographic process. In various embodiments, a thin film encapsulation (TFE) layer or layer stack may then be applied over the color filter materials to provide protection against air or moisture ingress into the quantum dot layers of the color conversion material. In one embodiment, the TFE may comprise a tri-layer stack of two silicon nitride layers separated by a polymer layer.

In an alternative embodiment, the color selector 114 comprises a distributed Bragg reflector (DBR) formed over the color conversion material (112a, 112b, 112c, 112d). The DBR may be configured to reflect pump photons 118 which are transmitted through the color conversion material back into the cavity 106 as reflected photons 122 (e.g., UV or deep blue photons) and to allow the converted photons 120 to be transmitted out of the cavity 106. The DBR may be formed as an alternating multi-layer stack of materials (not shown) having different indices of refraction. For example, the DBR may be formed as a stack of N layers alternating between TiO₂ (n=2.5) and SiO₂ (n=1.5) with N being 2 or more. In other embodiments, various other materials having respective indices of refraction may be used in constructing the DBR.

Embodiments in which the DBR includes TiO₂ and SiO₂ with N=2 may have a bandwidth of 164 nm at a center wavelength of 405 nm and a maximum reflectivity R of 84%. Embodiments in which the DBR stack includes a larger number of layers (i.e., N>2) may have increased reflectivity. As such, the probability of a UV pump photon 118 passing through the DBR may be decreased. The UV reflected photons 122 reflected from the DBR back into the cavity 106 may circulate through the color conversion material (112a, 112b, 112c, 112d) and may thereby have an increased probability of also being converted to converted photons 120 having the target wavelength (e.g., green, blue, or red). In this way, any UV reflected photons 122 that are not initially absorbed by the color conversion material (112a, 112b, 112c, 112d) may eventually be absorbed and converted to converted photons 120 having the target emission wavelength. This process, which is sometimes called “photon recycling” may increase the quantum efficiency of the device.

If the micro-LEDs 102 comprise shorter wavelength blue light emitting LEDs, then the DRB 114 may block the shorter wavelength blue light (i.e., pump photons 118) of the micro-LEDs 102 but transmit the longer wavelength converted photons 120 emitted from blue quantum dots of the color conversion material. Alternatively, the DBR 114 may be omitted over the blue light emitting subpixels.

The DBR may be formed by a deposition (e.g., by evaporation) of a multi-layer stack (not shown) over all of the subpixels. As such, the DBR may provide additional protection against moisture and oxygen ingress into the quantum dot layer. A higher value of N may further increase both the DBR reflectivity and the protection from moisture and oxygen, leading to improved overall system performance and durability.

In various additional embodiments, other materials may be used for the various components of the device. For example, the DBR may include a wide range of materials each having respective refractive indices, for example, nitrides (TiN, AlN, TiN, etc.), polysilicon, etc. Some embodiments may include multiple layers of quantum dots, multiple DBR structures, etc. The light extracting material layer 110, described above, may be omitted in some embodiments or multiple light extraction material layers 110 may be used. By using a more effective DBR 114, the layer thickness and density of the color conversion material (112a, 112b, 112c, 112d) may be reduced. In further embodiments, the optical cavities 106 may be formed in various ways. For example, the optical cavities 106 may be formed in a separate matrix layer which may then be attached to the array of micro-LEDs 102 after the optical cavities 106 are formed, as described in greater detail below. Further embodiments may also include light-collimating elements to mitigate performance degradation that may otherwise occur due to lateral photon propagation.

FIG. 1E is a vertical cross-sectional view of a further array 100e of light emitting devices, according to various embodiments. As shown, the array 100e of light emitting devices includes micro lenses 124 formed over optical cavity 106. Each micro lens 124 may help to improve light extraction from each micro-LED structure and may thereby improve efficiency of the array 100e. In general, extraction of light emitted by micro-LEDs may be increasingly challenging with decreasing pixel pitch and micro-LED size. In this regard, the color conversion material (112a, 112b, 112c, 112d) may be chosen to be sufficiently thick to convert all of the pump photons 118 into converted photons 120, each having a specific color. The thickness of the color conversion material (112a, 112b, 112c, 112d) may be very large compared to a lateral dimension of the subpixel. In such a structure, photons may move diffusively rather than ballistically out of the micro-LED subpixel. Such diffusively moving photons may spread to adjacent subpixels, potentially causing optical cross talk.

Disclosed embodiments provide improved optical extraction of photons (e.g., along a specific direction) generated by the quantum dots, while maintaining high efficiency by avoiding loss of photons to absorbing surfaces. As described above, this may be accomplished by forming a matrix structure that include cavity walls 108 that are reflective, including a light extracting material layer 110, and/or including a color selector 114, such as a DBR.

The use of quantum dots as a color conversion material (112a, 112b, 112c, 112d) for micro-LED displays may include deposition and patterning of dense quantum dot layers at very small feature sizes. To achieve sufficient absorption of pump photons 118 (e.g., see FIGS. 1D and 1E) in the quantum dot layer, subpixels with aspect ratios of greater than 1:1 may be used. Such subpixels may also be separated by cavity walls 108 formed of an opaque matrix material to prevent color crosstalk (i.e., photons from one micro-LED propagating into neighboring subpixels) in the display.

A high concentration of quantum dots used as a color conversion material (112a, 112b, 112c, 112d) may present additional challenges for fabrication of high-resolution structures. Since quantum dots strongly absorb UV light, the activity of photoinitiators or photo-acid generators, that are generally used in photoresists, may be diminished. Thus, the presence of quantum dots may require conventional fabrication materials and methods to be modified. As such, the patterning of tall and thin structures may be more difficult when using high loadings of quantum dots. Disclosed embodiments solve this problem by forming cavities as vias etched in a matrix material, as described in greater detail with reference to FIGS. 3A to 4P, below.

Various embodiments include a matrix, such as a matrix 200a or 200b, which may allow better light extraction from each subpixel and may mitigate photonic color crosstalk. Using the matrix as a template and sequentially opening vias corresponding to different color subpixels allows the deposition and curing of quantum dot inks without relying on a high-resolution photo-patternable resin formulation. Various embodiments, described below, include opening of vias corresponding to one color in a matrix layer, filling with quantum dot ink, curing and encapsulation, then repeating the same process with the second color, the third color, etc.

FIGS. 3A to 3L are vertical cross-sectional views of intermediate structures that may be used in the formation of an array of light emitting devices, according to various embodiments. As shown in FIG. 3A, a continuous matrix layer 304L may be deposited on a support 302. In one embodiment, the continuous matrix layer 304L may have a thickness of approximately 10 to 30 microns. The matrix layer 304L may comprise an insulating material, such as silica, alumina, titania, etc. to form the optical cavity walls 108 described above with respect to FIG. 1B. Alternatively, the matrix layer 304L may comprise a metal, such as aluminum which is then anodized to form anodic alumina. In another alternative embodiment, the matrix layer 304L may be a reflective metal, such as aluminum, which is not converted to a metal oxide. In this alternative embodiment, the matrix layer 304L is formed over the micro-LEDs 102 in such a manner as to avoid electrically shorting corresponding electrodes of adjacent micro-LED 102 to each other.

The support 302 may comprise the backplane 104 supporting the micro-LEDs 102 as described above with respect to FIG. 1A. In an alternative embodiment, the support 302 may comprise a separate substrate, such as a transparent glass or polymer substrate which is subsequently attached over the backplane 104 supporting the micro-LEDs 102.

As shown in FIG. 3B, a patterned mask material 306 may be formed over the continuous matrix layer 304L. In one embodiment, the patterned mask material 306 may be a photoresist and may be patterned using photolithography techniques.

The continuous matrix layer 304L (e.g., see FIG. 3A) may be etched to form an etched matrix layer 304 that includes first vias 308a. In an exemplary embodiment, a continuous aluminum matrix layer 304L may be etched using a BCl₃ dry etch process. The first vias 308a may correspond to optical cavities 106 for a first plurality of subpixels. For example, the first plurality of subpixels may correspond to a first color (e.g., red, green or blue color). After etching, the patterned mask material 306 may be removed.

As shown in FIG. 3C, the patterned mask material 306 (e.g., see FIG. 3B) may be removed and replaced by a ultrahydrophobic (i.e., nonstick) coating 310. The coating 310 may comprise a fluorinated silane coating, such as inorganic nanoparticles (e.g., silica nanoparticles) functionalized with a fluoroalkylsilane groups. A quantum dot ink, having a plurality of first quantum dots 112a, may then be deposited by spin-coating, doctor-blading, inkjet-printing, or other method to fill the first vias 308a, as shown in FIG. 3D. The fluorinated coating 310 may ensure that the majority of quantum dots do not stick to a top surface of the structure. The quantum dot ink may then be cured either by UV irradiation or by heating. The fluorinated coating 310 and excess quantum dots may then be washed off, as shown in FIG. 3E.

A protective layer 314 may then be formed over the first quantum dots 112a, as shown in FIG. 3F. For example, the protective layer 314 may be a layer of alumina that may be deposited by atomic layer deposition (ALD). In an exemplary embodiment, the protective layer 314 may have a thickness of 3 to 10 nm, such as approximately 5 nm. Other embodiments may include other thicknesses, other materials, and other deposition methods for the protective layer 314.

The above-described process (e.g., see FIGS. 3A to 3F) may then be repeated to deposit and cure quantum dot inks for other colors. For example, a patterned mask material 306 may be formed over the intermediate structure of FIG. 3F and an etch process may be performed to form second vias 308b through the protective layer 314, as shown in FIG. 3G. The patterned mask material 306 may be removed and replaced by the above described ultrahydrophobic (i.e., nonstick) fluorinated coating 310, as shown in FIG. 3H. A quantum dot ink having a plurality of second quantum dots 112b (i.e., different color dots from the dots 112a) may then be deposited by spin-coating, doctor-blading, inkjet-printing, or other method to fill the second vias 308b, as shown in FIG. 3I. The fluorinated coating 310 and excess quantum dots may then be washed off, as shown in FIG. 3J. A second protective layer having a first portion 314a and a second portion 314b may then be formed over the second quantum dots 112b, as shown in FIG. 3K. The first portion 314a may be formed over the existing first protective layer 314, while the second portion 314b may be formed over the second vias 308b filled with the second quantum dots 112b.

Similarly, the process may be continued to form third vias 308c, as shown in FIG. 3L. The third vias 308c may be filled with a third quantum dot ink including third quantum dots 112c (not shown in this figure). In various embodiments, the process may be continued to form additional vias that may be filled with quantum dots corresponding to additional respective colors.

If the support 302 comprises a transparent substrate, then the support 302 supporting the completed matrix containing the quantum dots may then be attached over the backplane 104 supporting the micro-LEDs 102. If the support 302 comprises the backplane 104 supporting the micro-LEDs 102, then the etched matrix layer 304 includes the cavity walls 108 surrounding the optical cavities 106 filled with the quantum dots (112a, 112b, etc.).

FIGS. 4A to 4P are vertical cross-sectional views of further intermediate structures that may be used in the formation of an array of light emitting devices, according to various embodiments. The processes of FIGS. 4A to 4P include providing matrix layer on support, deposition of a planar positive photoresist layer, and selective exposure and removal of this photoresist for sequentially opening vias. The processes of FIGS. 4A to 4P rely on removal of a photoresist to form the optical cavities. As such, in certain embodiments, the second process flow (i.e., described below with reference to FIGS. 4A to 4P) may be more versatile, cheaper, and safer.

As shown in FIG. 4A, a first intermediate structure may include a continuous matrix layer 108L formed over the above described support 302. The matrix layer 108L may comprise an insulating layer, such as alumina, silica, titania, etc., or a conductive layer, such as a metal layer, for example aluminum. A patterned photoresist 406 may be formed over continuous matrix layer 108L. In this regard, a blanket layer of photoresist (not shown) may be formed over the continuous matrix layer 108L and may be patterned using photolithography techniques to form the patterned photoresist 406.

As shown in FIG. 4B, using the patterned photoresist 406 as a mask layer, the continuous matrix layer 108L may be etched to form vias or cavities (e.g., optical cavities) 106 that are bounded by cavity walls 108, as shown in FIG. 4B. The patterned photoresist 406 may then be removed by ashing or by dissolution with a solvent.

In an alternative embodiment, rather than etching the continuous matrix layer 108L, the cavity walls 108 may be formed by anodic oxidation. As described above, if the continuous matrix layer 108L comprises aluminum, then it may be anodized in acid as described above to form the porous anodic alumina layer containing cavity walls 108 surrounding the optical cavities (i.e., pores) 106.

As shown in FIG. 4C, a positive photoresist, having a first photoresist portion 408a, a second photoresist portion 408b, and a third photoresist portion 408c, may then be deposited over the intermediate structure of FIG. 4B into the optical cavities 106. Each photoresist portion fills the respective optical cavity 106.

As shown in FIG. 4D, an optional patterned mask 410 may be used with a UV radiation source (e.g., UV emitting lamp) 412 to selectively expose the first photoresist portion 408a of the positive photoresist through the mask 410 to UV radiation 414. Exposure of the first photoresist portion 408a of the positive photoresist makes the first photoresist portion 408a soluble in a photoresist developer, which may be used to remove the first photoresist portion 408a of the positive photoresist. The second and third photoresist portions are not exposed to UV radiation.

Alternatively, if the support 302 comprises the backplane 104 supporting UV radiation emitting micro-LEDs 102, then the micro-LED 102 located under the first photoresist portion 408a may be activated to irradiate the first photoresist portion 408a with UV radiation from the bottom to render the portion 408a soluble in the developer. In this alternative embodiment, the mask 410 and the radiation source 412 may be omitted. The micro-LED 102 located under the second and third photoresist portions 408b, 408c are not activated.

As shown in FIG. 4E, first vias 416a may be generated by removing the first photoresist portion 408a without removing the other photoresist portions 408b, 408c by immersing the structure in photoresist developer bath or spraying the positive photoresist with the developer solution.

As shown in FIG. 4F, a first quantum dot ink 418a may then be introduced into the first vias 416a. The first vias 416a may thereby be filled with a uniform layer of first quantum dots 112a. A polymer in which the first quantum dots 112a are suspended may then be cured thermally or by exposure to UV radiation. For example, FIG. 4G illustrates selective exposure of the first quantum dots 112a to UV radiation using the patterned mask 410 and the source 412 of UV radiation. Alternatively, the UV emitting micro-LEDs 102 underlying the first quantum dots 112a may be activated to irradiate the first quantum dots 112a with UV radiation.

The above-described process shown in FIGS. 4C to 4G may then be repeated to form second quantum dots 112b in second optical cavities 106. In this regard, the second photoresist portion 408b of the positive photoresist shown in FIG. 4C may be exposed to UV radiation from the UV radiation source 412 or from the micro-LEDs 102, as shown in FIG. 4H. The second photoresist portion 408b of the positive photoresist may then be removed with a photoresist developer to thereby generate second vias 416b, as shown in FIG. 4I. The second quantum dot ink 418b may then be introduced into the second vias 416b to thereby form the uniform layer of second quantum dots 112b, as shown in FIG. 4J. The uniform layer of second quantum dots 112b may then be cured by exposure to UV radiation from the UV radiation source 412 or from the micro-LEDs 102, as shown in FIG. 4K.

The above-described process shown in FIGS. 4C to 4G may then be repeated to form third quantum dots 112c in third optical cavities 106. In this regard, the third photoresist portion 408c of the positive photoresist may be exposed to UV radiation from the UV radiation source 412 or from the micro-LEDs 102, as shown in FIG. 4L. The third photoresist portion 408c of the positive photoresist may then be removed with a photoresist developer to thereby generate third vias 416c, as shown in FIG. 4M. The third quantum dot ink 418c may then be introduced into the third vias 416c to thereby form the uniform layer of third quantum dots 112c, as shown in FIG. 4N. The uniform layer of third quantum dots 112c may then be cured thermally or by exposure to UV radiation from the UV radiation source 412 or from the micro-LEDs 102, as shown in FIG. 4O.

Lastly, a protective layer 314 may then be formed over the uniform layer of first quantum dots 112a, the uniform layer of second quantum dots 112b, the uniform layer of third quantum dots 112c, and the cavity walls 108, as shown in FIG. 4P. As described above, the protective layer 314 may be an alumina layer that is deposited by ALD. Other materials and deposition processes may be used to deposit the protective layer 314 and/or the color selector 114 (e.g., DBR) as described above.

In the above-described embodiments, the shape of subpixels in an array of light emitting devices may be defined by the geometry of the cavities/vias. As such, the patternability requirements for the quantum dot inks (418a, 418b, 418c) may be significantly less stringent than requirements for embodiments that do not rely on a matrix template. In some embodiments, a UV curable quantum dot ink may be used for confining the quantum dots to the targeted subpixels. In other embodiments, thermally curable inks may also be used. The use of UV curable or thermally curable quantum dot inks enhances the choice of chemistries that may be used in forming the (quantum dot based) color conversion material (112a, 112b, 112c, 112d).

Various embodiments may include solvent-based or solvent-free quantum dot inks. The use of thermal curing for the quantum dot inks in each subpixel allows omission of photocurable acrylates/epoxies for the ink formulation. In further embodiments, quantum dot inks may be formed using inorganic ligands and matrix materials (for example, metal chalcogenides and metal oxides), which may offer alternative benefits such as high temperature stability.

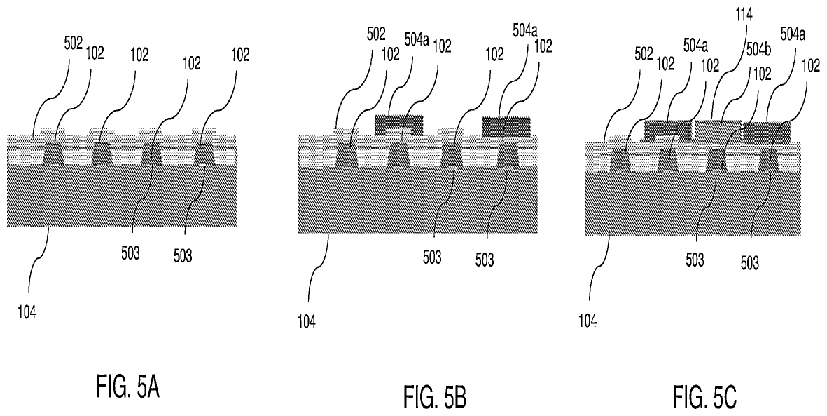

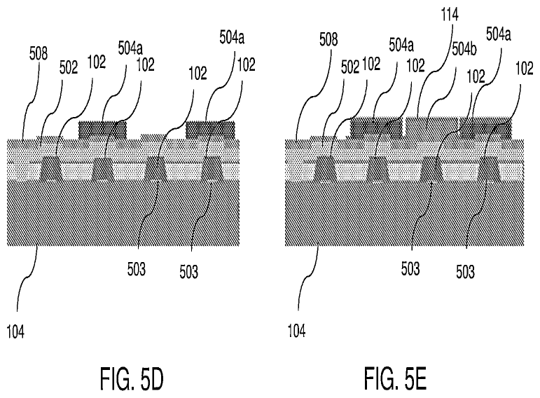

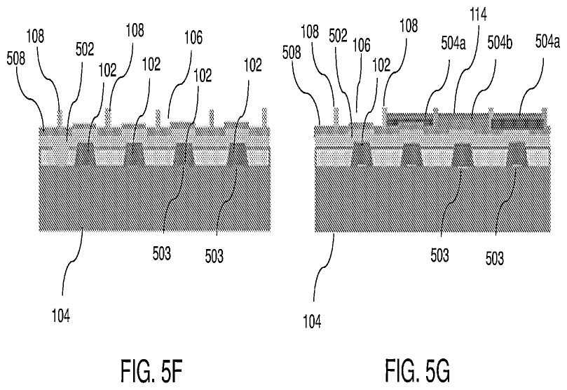

FIGS. 5A to 5G are vertical cross-sectional views of further intermediate structures that may be used in the formation of an array of light emitting devices, according to various embodiments. As shown in FIG. 5A, a plurality of micro-LEDs 102 may be formed on a substrate 104. The substrate 104 may be a backplane having electrical circuitry (e.g., CMOS or TFT circuits) configured to supply voltages to the micro-LEDs 102 to thereby control light emission by the micro-LEDs 102. As described above, the micro-LEDs 102 may comprise blue or UV emitting LEDs. The intermediate structure of FIG. 5A may include a common cathode 502 for plural micro-LEDs 102 formed of a transparent conducting oxide (e.g., indium tin oxide) and separate anodes 503 for each micro-LED 102 which electrically connected to respective backplane circuitry (not shown for clarity). Thus, plural micro-LEDs 102 are shorted on their cathode (e.g., n-type) side, but are separately activated by the backplane circuitry on their anode (e.g., p-type) side. The common cathode 502 is also connected to the backplane circuitry outside of the micro-LED 102 area.

In one embodiment, the micro-LEDs 102 may comprise vertical LEDs with cathode and anode electrodes (502, 503) located on opposite sides of the LED. In one embodiment, the micro-LEDs 102 may have a reverse taper. In other words, the micro-LEDs 102 may be wider on the bottom side facing the anode 503 and the backplane 104, than on the top side facing the common cathode 502.

As shown in FIG. 5B, a first color conversion material (e.g., first color quantum dots) 504a may be formed over a first plurality of the micro-LEDs 102. The first color conversion material 504a may be formed by an ink jet process that may be used to print a first quantum dot ink only directly over first portions of the common cathode 502 over respective micro-LEDs 102 in the first color subpixels. Alternatively a continuous quantum dot layer may be deposited directly on the common cathode, followed by photolithography and patterning to leave the first color quantum dots 504a only over the respective micro-LEDs 102 in the first color subpixels.

As shown in FIG. 5C, a second color conversion material 504b may be formed over a second plurality of the micro-LEDs 102. The second color conversion material 504b may be formed by an ink jet process that may be used to print a second quantum dot ink directly over second portions of the common cathode 502 over respective micro-LEDs 102 or by depositing a continuous quantum dot layer followed by photolithographic patterning. The color conversion material may be omitted over blue emitting micro-LEDs 102. Alternatively, a blue color conversion material may be formed over UV emitting micro-LEDs 102. Lastly, a respective color selector 114 may be formed over the first color conversion material 504a and the second color conversion material 504b. For example, the color selector 114 may be a DBR, as described above. If desired, an encapsulating layer, such as an alumina layer, may be formed over the color selector 114.

Alternatively, the intermediate structures of FIGS. 5B and 5C may be formed using processes similar to those described above with reference to FIGS. 4A to 4P. In this regard, a patterned photoresist (not shown) may be formed over the common cathode 502 and may be used as a mask material for deposition of the first color conversion material 504a. In this regard, the mask material may include openings corresponding to places over which the first color conversion material 504a is to be deposited. After the first color conversion material 504a has been deposited and cured, the photoresist may be patterned to form openings corresponding to places over which the second color conversion material 504b is to be deposited, etc.

In further embodiments, the intermediate structures of FIGS. 5D and 5E may be formed by forming an etch stop layer 508 over the common cathode 502 of the structure of FIG. 5A. The first color conversion material 504a and the second color conversion material 504b may then be deposited, as shown in FIGS. 5D and 5E. The etch stop layer 508 may comprise silicon oxide or other similar etch stop materials. The presence of the etch stop layer 508 may protect the transparent conductive oxide that forms the common cathode 502 during processes in which the photoresist is etched.

The processes of forming the additional alternative intermediate structures of FIGS. 5F and 5G may be similar to the processes used to form the intermediate structures of FIGS. 5D and 5E from the intermediate structure of FIG. 5A. In this regard, each of the intermediate structures of FIGS. 5F and 5G may include the etch stop layer 508 of FIGS. 5D and 5E formed over the common cathode 502 of FIG. 5A. The intermediate structures of FIGS. 5F and 5G may further include optical cavities 106 bounded by cavity walls 108. The optical cavity 106 over the blue subpixel may remain unfilled if the micro-LEDs 102 comprise blue LEDs. As such, the intermediate structures of FIGS. 5F and 5G may be similar to the embodiments of FIGS. 1B to 1E, 3L, and 4B to 4P.

The preceding description of the disclosed embodiments is provided to enable persons of ordinary skill in the art to make or use the disclosed embodiments. Various modifications to these embodiments will be readily apparent to those of ordinary skill in the art, and the generic principles defined herein may be applied to other embodiments without departing from the spirit or scope of the disclosure. Thus, the disclosure is not intended to be limited to the embodiments shown herein but is to be accorded the widest scope consistent with the following claims and the principles and novel features disclosed herein.

What is claimed is:

1. A light emitting device, comprising:
a first optical cavity bounded by at least one first cavity wall;
a first light emitting diode located in the first optical cavity and configured to emit blue or ultraviolet radiation first incident photons;
a first color conversion material located over the first light emitting diode and configured to absorb the first incident photons emitted by the first light emitting diode and to generate first converted photons having a longer peak wavelength than a peak wavelength of the first incident photons; and
a first color selector located over the first color conversion material and configured to absorb or reflect the first incident photons and to transmit the first converted photons.

2. The light emitting device of claim 1, wherein the first light emitting diode (LED) comprises a micro-LED having a length and width less than 100 microns and containing an undoped GaN or an InGaN light emitting layer.

3. The light emitting device of claim 1, wherein the first color conversion material comprises a layer of quantum dots.

4. The light emitting device of claim 3, wherein the layer of quantum dots is configured to absorb the first incident photons and to emit the first converted photons having a color that is red, green, or blue.

5. The light emitting device of claim 1, wherein the first color selector comprises a color filter comprising an organic dye embedded in an organic polymer.

6. The light emitting device of claim 1, wherein the first color selector comprises a distributed Bragg reflector.

7. The light emitting device of claim 1, wherein the at least one first cavity wall comprises an insulating metal oxide material.

8. The light emitting device of claim 1, further comprising a light extracting material located in the first optical cavity between the first light emitting diode and the first color conversion material, wherein the light extracting material has a first index of refraction that is less than a second index of refraction of the at least one first cavity wall.

9. The light emitting device of claim 1, further comprising:
a second optical cavity bounded by at least one second cavity wall;
a second light emitting diode located in the second optical cavity and configured to emit blue or ultraviolet radiation second incident photons;
a second color conversion material located over the second light emitting diode and configured to absorb the second incident photons emitted by the light emitting diode and to generate second converted photons having a longer peak wavelength than a peak wavelength of the second incident photons and the peak wavelength of the first converted photons;
a second color selector located over the second color conversion material and configured to absorb or reflect the second incident photons and to transmit the second converted photons;
a third optical cavity bounded by at least one third cavity wall;
a third light emitting diode located in the third optical cavity and configured to emit blue or ultraviolet radiation third incident photons;
a third color conversion material located over the third light emitting diode and configured to absorb the third incident photons emitted by the light emitting diode and to generate third converted photons having a longer peak wavelength than a peak wavelength of the third incident photons, the peak wavelength of the first converted photons and the peak wavelength of the second converted photons; and
a third color selector located over the third color conversion material and configured to absorb or reflect the third incident photons and to transmit the third converted photons.

10. The light emitting device of claim 1, further comprising a backplane supporting the first, second and third light emitting diodes, wherein the at least one first, second and third cavity walls comprise portions of a matrix layer located over the backplane and containing the first, second and third optical cavities therein.

11. A method of forming an array of light emitting devices, comprising:
forming a first via in a matrix material;
depositing a first plurality of quantum dots in the first via to form a first portion of the color conversion material layer corresponding to a first color;
forming a second via in the matrix material;
depositing a second plurality of quantum dots in the second via to form a second portion of the color conversion material layer corresponding to a second color;
forming a third via in the matrix material; and
depositing a third plurality of quantum dots in the third via to form a third portion of the color conversion material layer corresponding to a third color,
wherein the first plurality of quantum dots are located over a first light emitting diode, the second plurality of quantum dots are located over a second light emitting diode, and the third plurality of quantum dots are located over a third light emitting diode.

12. The method of claim 11, further comprising:
forming a first protective layer over the first plurality of quantum dots prior to forming the second via in the matrix material; and
forming a second protective layer over the second plurality of quantum dots prior to forming the third via in the matrix material.

13. The method of claim 11, further comprising:
forming a first positive photoresist portion in the first via, forming a second positive photoresist portion the second via, and forming a third positive photoresist portion the third via during a same positive photoresist deposition step, wherein the forming the first, the second and the third via in the matrix material occur during a same via formation step;
selectively exposing and removing the first positive photoresist portion covering the first via prior to the depositing the first plurality of quantum dots in the first via;
selectively exposing and removing a second positive photoresist portion covering the second via after the depositing the first plurality of quantum dots in the first via and prior to the depositing the second plurality of quantum dots in the second via; and
selectively exposing and removing the third positive photoresist positive portion covering the third via after the depositing the second plurality of quantum dots in the second via and prior to the depositing the third plurality of quantum dots in the third via.

14. The method of claim 13, wherein:
the first, the second and the third light emitting diodes are located over a backplane;
the matrix material is formed over the first, the second and the third light emitting diodes prior to the forming the first, the second and the third via in the matrix material;
the selectively exposing the first positive photoresist portion comprises activating the first light emitting diode to expose the first positive photoresist portion;
the selectively exposing the second positive photoresist portion comprises activating the second light emitting diode to expose the second positive photoresist portion; and
the selectively exposing the third positive photoresist portion comprises activating the third light emitting diode to expose the third positive photoresist portion.

15. The method of claim 11, wherein:
the first, the second and the third light emitting diodes are located over a backplane;
the matrix material is formed over the first, the second and the third light emitting diodes prior to the forming the first, the second and the third via in the matrix material; and
the matrix material comprises a metal or a metal oxide layer.

16. The method of claim 15, wherein:
the matrix material is formed as an aluminum layer over the first, the second and the third light emitting diodes; and
the forming the first, the second and the third via in the matrix material comprises anodically oxidizing the aluminum layer by applying a voltage to electrodes of the first, the second and the third light emitting diodes in an acid bath to form an alumina matrix material.

17. The method of claim 11, further comprising:
forming a first color selector over the first plurality of quantum dots in the first via;
forming a second color selector over the second plurality of quantum dots in the second via; and
forming a third color selector over the third plurality of quantum dots in the third via.

18. The method of claim 17, wherein the first, the second and the third color selectors comprise an organic dye color filter embedded in an organic polymer.

19. The method of claim 17, wherein the first, the second and the third color selector comprise a distributed Bragg reflector.

20. The method of claim 11, further comprising forming a light extracting material over the first, the second and the third light emitting diode prior to forming the first, the second and the third color selector, wherein the light extracting material has a first index of refraction that is less than a second index of refraction of the matrix material.
